(19) United States
(12) Patent Application Publication
(10) Pub. No.: US 2025/0254795 A1
(43) Pub. Date: Aug. 7, 2025

(54) WIRING SUBSTRATE

(71) Applicant: IBIDEN CO., LTD., Ogaki (JP)

(72) Inventors: Toshiki FURUTANI, Ibi-gun (JP); Masashi KUWABARA, Ibi-gun (JP)

(73) Assignee: IBIDEN CO., LTD., Ogaki (JP)

(21) Appl. No.: 19/189,374

(22) Filed: Apr. 25, 2025

Related U.S. Application Data
(63) Continuation of application No. PCT/JP2023/039116, filed on Oct. 30, 2023.

(30) Foreign Application Priority Data
Nov. 2, 2022 (JP) 2022-176442

(51) Int. Cl. H05K 1/14; H05K 1/11; H05K 1/18

(52) U.S. Cl. CPC H05K 1/144; H05K 1/112; H05K 1/181; H05K 2201/0266; H05K 2201/041; H05K 2201/068

(57) ABSTRACT

A wiring substrate includes a first wiring substrate including first insulating layers, first conductor layers, and first via conductors, and a second wiring substrate mounted on the first substrate and including second insulating layers, second conductor layers, and second via conductors. The second substrate is formed such that the minimum wiring width of wirings in the second conductor layers is smaller than the minimum wiring width of wirings in the first conductor layers, the minimum inter-wiring distance of the wirings in the second conductor layers is smaller than the minimum inter-wiring distance of the wirings in the first conductor layers, the wiring widths of the wirings in the second conductor layers are 3 μm or less, the inter-wiring distances of the wirings in the second conductor layer are 3 μm or less, and aspect ratio of the wirings in the second conductor layer is in range of 2.0 to 4.0.

### CROSS-REFERENCE TO RELATED APPLICATIONS

The present application is a continuation of and claims the benefit of priority to International Application No. PCT/JP2023/039116, filed Oct. 30, 2023, which is based upon and claims the benefit of priority to Japanese Application No. 2022-176442, filed Nov. 2, 2022. The entire contents of these applications are incorporated herein by reference.

### BACKGROUND OF THE INVENTION

### Field of the Invention

The present invention relates to a wiring substrate.

### Description of Background Art

Japanese Patent Application Laid-Open Publication No. 2020-191323 describes a semiconductor package. The entire contents of this publication are incorporated herein by reference.

### SUMMARY OF THE INVENTION

According to one aspect of the present invention, a wiring substrate includes a first wiring substrate including first insulating layers, first conductor layers, and first via conductors penetrating through the first insulating layers, and a second wiring substrate mounted on a surface of the first wiring substrate and including second insulating layers, second conductor layers, and second via conductors penetrating through the second insulating layers. The second wiring substrate is formed such that the minimum wiring width of wirings in the second conductor layers is smaller than the minimum wiring width of wirings in the first conductor layers, the minimum inter-wiring distance of the wirings in the second conductor layers is smaller than the minimum inter-wiring distance of the wirings in the first conductor layers, the wiring widths of the wirings in the second conductor layers are 3 μm or less, the inter-wiring distances of the wirings in the second conductor layer are 3 μm or less, and an aspect ratio of the wirings in the second conductor layer is in the range of 2.0 to 4.0.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a partial enlarged cross-sectional view illustrating an example of the wiring substrate illustrated in FIG. 1;

FIG. 3 is a partial enlarged view illustrating another example of the wiring substrate illustrated in FIG. 2.

FIG. 4A illustrates an example of a method for manufacturing a wiring substrate according to an embodiment of the present invention;

FIG. 4B illustrates an example of a method for manufacturing a method for manufacturing a wiring substrate according to an embodiment of the present invention;

FIG. 4C illustrates an example of a method for manufacturing a method for manufacturing a wiring substrate according to an embodiment of the present invention;

FIG. 4D illustrates an example of a method for manufacturing a method for manufacturing a wiring substrate according to an embodiment of the present invention;

FIG. 5A illustrates an example of a method for manufacturing a method for manufacturing a wiring substrate according to an embodiment of the present invention;

FIG. 5B illustrates an example of a method for manufacturing a method for manufacturing a wiring substrate according to an embodiment of the present invention;

FIG. 5C illustrates an example of a method for manufacturing a method for manufacturing a wiring substrate according to an embodiment of the present invention;

FIG. 5D illustrates an example of a method for manufacturing a method for manufacturing a wiring substrate according to an embodiment of the present invention;

FIG. 5E illustrates an example of a method for manufacturing a method for manufacturing a wiring substrate according to an embodiment of the present invention;

FIG. 5F illustrates an example of a method for manufacturing a method for manufacturing a wiring substrate according to an embodiment of the present invention;

FIG. 5G illustrates an example of a method for manufacturing a method for manufacturing a wiring substrate according to an embodiment of the present invention;

FIG. 5H illustrates an example of a method for manufacturing a method for manufacturing a wiring substrate according to an embodiment of the present invention;

FIG. 5I illustrates an example of a method for manufacturing a method for manufacturing a wiring substrate according to an embodiment of the present invention;

FIG. 5J illustrates an example of a method for manufacturing a method for manufacturing a wiring substrate according to an embodiment of the present invention;

FIG. 5K illustrates an example of a method for manufacturing a method for manufacturing a wiring substrate according to an embodiment of the present invention;

FIG. 5L illustrates an example of a method for manufacturing a method for manufacturing a wiring substrate according to an embodiment of the present invention; and

FIG. 6 illustrates another example of a method for manufacturing a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

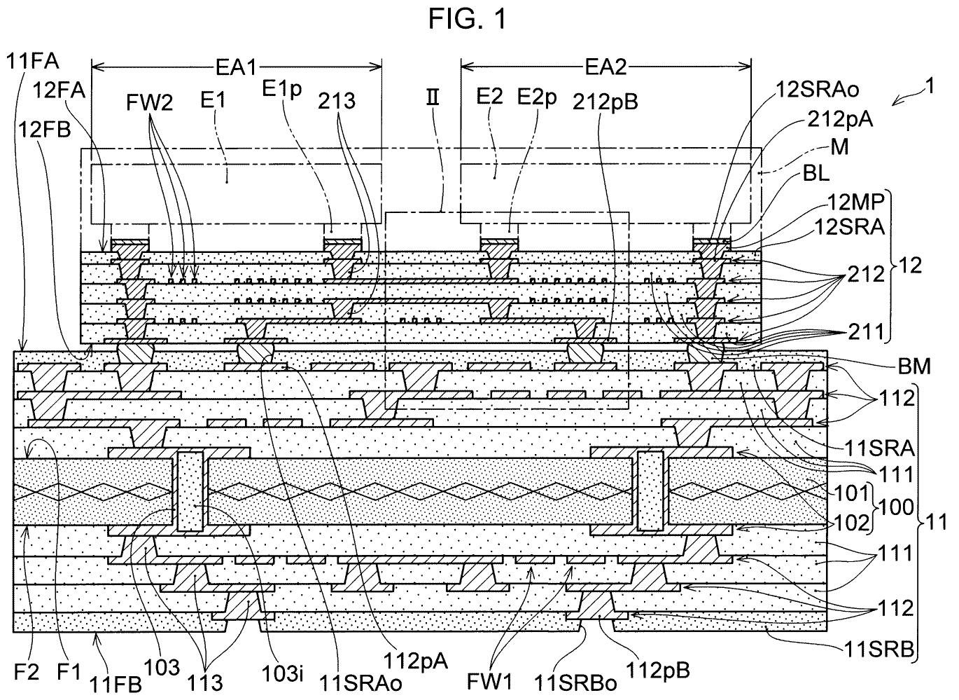

A wiring substrate according to an embodiment of the present invention is described with reference to the drawings. FIG. 1 is a cross-sectional view illustrating a wiring substrate 1, which is an example of the wiring substrate of the embodiment. As illustrated in FIG. 1, the wiring substrate 1 includes a first wiring substrate 11 and a second wiring substrate 12. In the illustrated example, the first wiring substrate 11 has a core substrate 100 that includes an insulating layer (core insulating layer) 101 and conductor layers (core conductor layers) 102 formed on both sides of the core insulating layer 101. On each of both sides of the core substrate 100, insulating layers and conductor layers are alternately laminated. In the illustrated example, multiple insulating layers 111 and multiple conductor layers 112 are alternately laminated on a first surface (F1) of the core substrate 100 and on a second surface (F2) of the core substrate 100.

The first wiring substrate 11 has, as its outermost surfaces (exposed surfaces) extending orthogonally to its thickness direction, a surface (11FA) on one side and a surface (11FB) on the other side (opposite side with respect to the surface (11FA)). The second wiring substrate 12 has multiple insulating layers 211 and multiple conductor layers 212, which are alternately laminated. The second wiring substrate 12 has, as its outermost surfaces (exposed surfaces) extending orthogonally to its thickness direction, an A surface (12FA) and a B surface (12FB) on an opposite side with respect to the A surface (12FA).

The A surface (12FA) of the second wiring substrate 12 is smaller than the surface (11FA) of the first wiring substrate 11. Specifically, a projected area of the second wiring substrate 12 when projected onto a horizontal plane of the wiring substrate 1 (a plane extending perpendicular to the thickness direction of the wiring substrate 1) is smaller than a projected area of the first wiring substrate 11 when projected onto the same horizontal plane. For example, when projected onto the horizontal plane of the wiring substrate 1, the second wiring substrate 12 has a square shape with 50 mm sides, and its projected area is 2500 mm². For example, when projected onto the horizontal plane of the wiring substrate 1, the first wiring substrate has a square shape with 70 mm sides, and its projected area is 4900 mm².

The second wiring substrate 12 is mounted on the surface (11FA) of the first wiring substrate 11. Specifically, in the illustrated example, conductor pads (112pA) forming the surface (11FA) of the first wiring substrate 11 and conductor pads (212pB) forming the B surface (12FB) of the second wiring substrate 12 are electrically connected via conductive connecting members (BM). That is, the wiring substrate of the embodiment includes the first wiring substrate 11 and the second wiring substrate 12 mounted on the surface (11FA) of the first wiring substrate 11.

The insulating layers 111 of the first wiring substrate 11 are also referred to as first insulating layers 111, and the conductor layers 112 of the first wiring substrate 11 are also referred to as first conductor layers 112. The insulating layers 211 of the second wiring substrate 12 are also referred to as second insulating layers 211, and the conductor layers 212 of the second wiring substrate 12 are also referred to as second conductor layers 212.

In the illustrated example, the first wiring substrate 11 has a covering insulating layer (11SRA) that forms the surface (11FA) and a covering insulating layer (11SRB) that forms the surface (11FB). The covering insulating layers (11SRA, 11SRB) can be, for example, solder resist layers that respectively form the outermost insulating layers of the wiring substrate 1. Openings (11SRAo) are formed in the covering insulating layer (11SRA), and the conductor pads (112pA) are exposed in the openings (11SRAo). The openings (11SRAo) are through holes that penetrate the covering insulating layer (11SRA) in the thickness direction, and the connecting members (BM) are positioned in the openings (11SRAo). Openings (11SRBo) are formed in the covering insulating layer (11SRB), and conductor pads (112pB) forming the surface (11FB) of the first wiring substrate 11 are exposed from the openings (11SRBo).

In the illustrated example, the A surface (12FA) of the second wiring substrate 12, which is on an opposite side with respect to the B surface (12FB) facing the first wiring substrate 11, is formed by a covering insulating layer (12SRA). Openings (12SRAo) that expose conductor pads (212pA) are formed in the covering insulating layer (12SRA), and connecting elements (12MP) are formed in the openings (12SRAo). The connecting elements (12MP) can function as conductor posts to be connected to connecting pads (E1p, E2p) of components (E1, E2) that can be mounted on the second wiring substrate 12. That is, in the illustrated example, the A surface (12FA) of the second wiring substrate 12, which is formed by the covering insulating layer (12SRA) and the connecting elements (12MP), is structured as a component mounting surface of the wiring substrate 1.

The insulating layers (101, 111, 211) of the wiring substrate 1 can each be formed, for example, using an insulating resin such as an epoxy resin or a phenol resin. A fluorine resin, a liquid crystal polymer (LCP), a fluoroethylene resin (PTFE), a polyester resin (PE), or a modified polyimide resin (MPI) also may be used for the insulating layers (101, 111, 211). The insulating layers (101, 111, 211) may each contain a reinforcing material (core material) such as a glass fiber. The insulating layers (101, 111, 211) can contain inorganic filler particles such as silica or alumina particles. The covering insulating layers (11SRA, 11SRB, 12SRA), which can be solder resist layers, can each be formed using, for example, a photosensitive epoxy resin or polyimide resin, or the like.

When the insulating layers (111, 211) contain inorganic filler particles, dimensions of the contained inorganic filler particles may differ depending on the insulating layers (111, 211). Specifically, in particular, a maximum particle size of inorganic filler particles that can be contained in the second insulating layers 211 of the second wiring substrate 12 may be smaller than a maximum particle size of inorganic filler particles contained in the first insulating layers 111 of the first wiring substrate 11. Further, relative permittivity and dielectric loss tangent of the second insulating layers 211 of the second wiring substrate 12 may differ from relative permittivity and dielectric loss tangent of the first insulating layers 111 of the first wiring substrate 11.

In the insulating layer 101 of the core substrate 100, through-hole conductors 103 are formed that penetrate the insulating layer 101 in the thickness direction and connect the conductor layer 102 forming the first surface (F1) of the core substrate 100 and the conductor layer 102 forming the second surface (F2) of the core substrate 100. Insides of the through-hole conductors 103 are each filled with a resin body (103i) containing an epoxy resin or the like. In each of the first insulating layers 111, via conductors 113 are formed that connect the conductor layers sandwiching the each of the first insulating layers 111. In each of the second insulating layers 211, via conductors 213 are formed that connect the conductor layers sandwiching the each of the second insulating layers 211. The via conductors 113 formed in the first insulating layers 111 are also referred to as first via conductors 113, and the via conductors 213 formed in the second insulating layers 211 are also referred to as second via conductors 213.

The conductor layers (102, 112, 212), the via conductors (113, 213), the through-hole conductors 103, and the connecting elements (12MP) can be formed using any metal such as copper or nickel, and, for example, can each be formed of a metal foil such as a copper foil and/or a metal film formed by plating or sputtering or the like. The conductor layers (102, 112, 212), the via conductors (113, 213), the through-hole conductors 103, and the connecting elements (12MP) are each illustrated in FIG. 1 as having a single-layer structure. However, it is also possible that they each have a multilayer structure that includes two or more metal layers. For example, the conductor layers 102 that are respectively formed on the surfaces of the insulating layer 101 can each have a five-layer structure including a metal foil layer (preferably, a copper foil), an electroless plating film layer (preferably, an electroless copper plating film), and an electrolytic plating film layer (preferably, an electrolytic copper plating film). Further, the conductor layers (112, 212), the via conductors (113, 213), the through-hole conductors 103, and the connecting elements (12MP) can each have, for example, a two-layer structure including a metal film layer, which is an electroless plating film or a sputtering film, and an electrolytic plating film layer. A functional layer (BL) that can function as a bonding layer between the components (E1, E2) and the connecting elements (12MP) can be formed on upper surfaces (end surfaces on an opposite side with respect to the conductor layer 212) of the connecting elements (12MP). The functional layer (BL) can be formed, for example, by a plating film of nickel, tin, palladium, gold, or the like.

The conductor layers (102, 112, 212) of the wiring substrate 1 are each patterned to have predetermined conductor patterns. In the illustrated example, the first conductor layers 112 include first wirings (FW1), and the second conductor layers 212 include second wirings (FW2). In the wiring substrate of the embodiment, in particular, the wirings (FW2) included in the second conductor layers 212 are formed as finer wirings than the wirings (FW1) included in the first conductor layers 112.

Specifically, a minimum wiring width of the second wirings (FW2) included in the second conductor layers 212 is smaller than a minimum wiring width of the first wirings (FW1) included in the first conductor layers 112. Further, a minimum inter-wiring distance (distance between wirings) of the second wirings (FW2) included in the second conductor layers 212 is smaller than a minimum inter-wiring distance of the first wirings (FW1) included in the first conductor layers 112. In other words, the second wiring substrate 12 includes the second wirings (FW2) that are the finest among the wirings that can be included in the conductor layers of the wiring substrate 1.

The conductor pads (212pA) included in the second conductor layer 212 closest to the A surface (12FA) of the second wiring substrate 12 can be electrically connected to an electronic component that can be mounted on the wiring substrate 1 via the connecting elements (12MP). Among the multiple conductor pads (212pA) illustrated in the drawing, the connecting elements (12MP) formed on the two conductor pads (212pA) illustrated on the left side are positioned in a first component mounting region (EA1), and the connecting elements (12MP) formed on the two conductor pads (212pA) illustrated on the right side are positioned in a second component mounting region (EA2). The component mounting regions (EA1, EA2) are regions in which the components (E1, E2) can be respectively mounted. Examples of the components (E1, E2) include electronic components (for example, logic chips and memory elements) such as active components such as semiconductor integrated circuit devices and transistors. As illustrated, the connecting elements (12MP) positioned in these different component mounting regions (EA1, EA2) may be connected by wirings included in the second wiring substrate 12. That is, the second conductor layers 212 may include so-called bridge wirings that electrically connect between the multiple connecting elements (12MP) that form the different component mounting regions. In using the wiring substrate 1, the multiple electronic components that can be mounted on the wiring substrate 1 can be electrically connected to each other through relatively short paths via the second wiring substrate 12.

Further, in particular, the second conductor layers 212 of the second wiring substrate 12 can be different from the conductor layers (102, 112) of the first wiring substrate 11 in thickness. Specifically, the thickness of each of the second conductor layers 212 can be smaller than the thickness of each of the conductor layers (102, 112) of the first wiring substrate 11. For example, when a minimum thickness of the conductor layers (112, 102) is 10 μm or more, a maximum thickness of the second conductor layers 212 can be 7 μm or less.

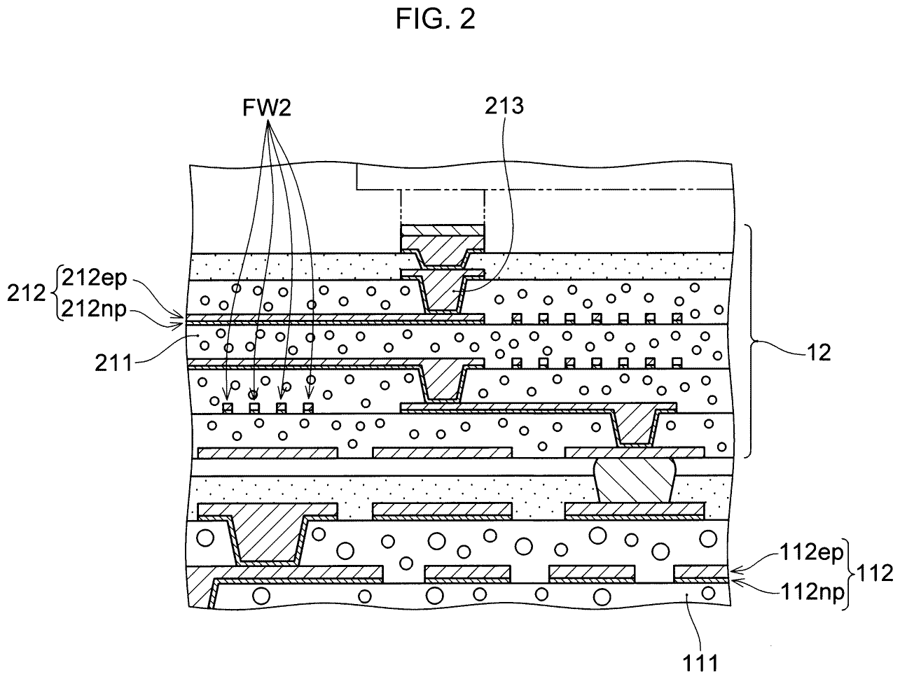

Next, with reference to FIG. 2, the structure of the second wiring substrate 12 of the wiring substrate 1 is described in detail. FIG. 2 is an enlarged view of a region (II) surrounded by a one-dot chain line in FIG. 1.

As described above, the second conductor layers 212 included in the second wiring substrate 12 include the wirings (FW2) that are the finest among the wirings included in the wiring substrate 1. Specifically, the wirings (FW2) included in the second conductor layers 212 are formed to have a minimum wiring width of 3 μm or less and a minimum inter-wiring distance of 3 μm or less. Further, the wirings (FW2) included in the second conductor layers 212 are formed to have an aspect ratio of 2.0 or more and 4.0 or less. In this way, since the second wiring substrate 12 includes the wirings (FW2) that have relatively small wiring widths and inter-wiring distances and relatively high aspect ratios, it is possible to provide a wiring substrate 1 that has highly reliable wirings provided at a relatively high density in a surface-layer part with reduced occurrence of a defect such as a disconnection. The via conductors 213 integrally formed with the conductor layers 212 included in the second wiring substrate 12 are formed to each have an aspect ratio ((depth from an upper surface of an insulating layer 211 to a bottom part of a via conductor 213)/(diameter at an upper side of the via conductor 213 (upper surface side of the insulating layer 211))) of 0.5 or more and 1.0 or less. The term “diameter” in the description of the via conductors 213 means a distance between two farthest points on an outer circumference in a horizontal cross section perpendicular to a depth direction of the via conductors 213.

Further, as described above, the dimensions of the inorganic filler particles that can be contained in the second insulating layers 211 of the second wiring substrate 12 can differ from the dimensions of the inorganic filler particles that can be contained in the other insulating layers of the wiring substrate 1. It may be possible that a maximum particle size of the inorganic filler particles that can be contained in the second insulating layers 211 is smaller than maximum particle sizes of the inorganic filler particles that can be contained in the other insulating layers of the wiring substrate 1. In the case where inorganic filler particles are contained in the second insulating layers 211 that are in contact with the wirings (FW2) formed at a relatively high density, when inorganic filler particles having relatively large particle sizes are positioned between adjacent wirings, a short circuit between the wirings may occur due to migration via surfaces of the filler particles. Therefore, since the maximum particle size of the filler particles that can be contained in the insulating layers 211 is relatively small, it may be possible that the risk of a short circuit in the wirings (FW2) is reduced. The term “particle size” in the description of the filler particles means a linear distance between two most distant points on an outer surface of a filler particle. Specifically, for example, the maximum particle size of the inorganic filler particles that can be contained in the second insulating layers 211 can be 1 μm or less.

In the illustrated example, the first conductor layers 112 and the second conductor layers 212 each have a two-layer structure including a metal film layer and an electrolytic plating film layer. In the illustration, the first conductor layers 112 each include a metal film layer (112np) and an electrolytic plating film layer (112ep), and the second conductor layers 212 each include a metal film layer (212np) and an electrolytic plating film layer (212ep). The metal film layer (112np) included in the first conductor layers 112 can be an electroless copper plating film layer formed by electroless plating. The electrolytic plating film layer (112ep) can be an electrolytic copper plating film layer formed using the metal film layer (112np) as a power feeding layer. In particular, the metal film layer (212np) of the second conductor layers 212 can be, for example, a sputtering film layer formed by sputtering with a copper target. The metal film layer (212np), which is a sputtering film layer, has relatively good adhesion to the upper surfaces of the insulating layers 211 and can have a more uniform thickness. The electrolytic plating film layer (212ep) can be an electrolytic copper plating film layer formed using the metal film layer (212np) as a power feeding layer.

As will be described in detail later regarding a method for manufacturing a wiring substrate, the formation of each of the second conductor layers 212 included in the second wiring substrate 12 may include a process of polishing the upper surface of the each of the second conductor layers 212. Therefore, the upper surface of each of the second conductor layers 212 can be flat with relatively low roughness, and thus, the conductor layers 212 (especially the second wirings (FW2)) can each have a relatively uniform thickness. Specifically, the upper surface of each of the second conductor layers 212 has an arithmetic mean roughness (Ra) of 0.3 μm or less. Since the second wirings (FW2) are formed to have relatively uniform thicknesses, an insertion loss of signals carried by the wirings (FW2) can be kept small. It is thought that good signal transmission by the wirings (FW2) can be realized.

The second wirings (FW2) included in the second conductor layers 212 can be wirings for high frequency signal transmission. Therefore, it is preferable that the insulating layers 211 in contact with the wirings (FW2) have excellent high-frequency characteristics. From a point of view of realizing good signal transmission quality for the signals carried by the wirings (FW2), the second insulating layers 211 desirably have relatively low relative permittivity and dielectric loss tangent. When an insulating layer in contact with a wiring has relatively high permittivity and dielectric loss tangent, a dielectric loss (transmission loss) of a high frequency signal transmitted via the wiring is relatively large. Therefore, the insulating layers 211 in contact with the wirings (FW2) are preferably formed of a material having relatively small permittivity and dielectric loss tangent, and preferably have, at a frequency of 5.8 GHz, a relative permittivity of 0.005 or less and a dielectric loss tangent of 4.0 or less.

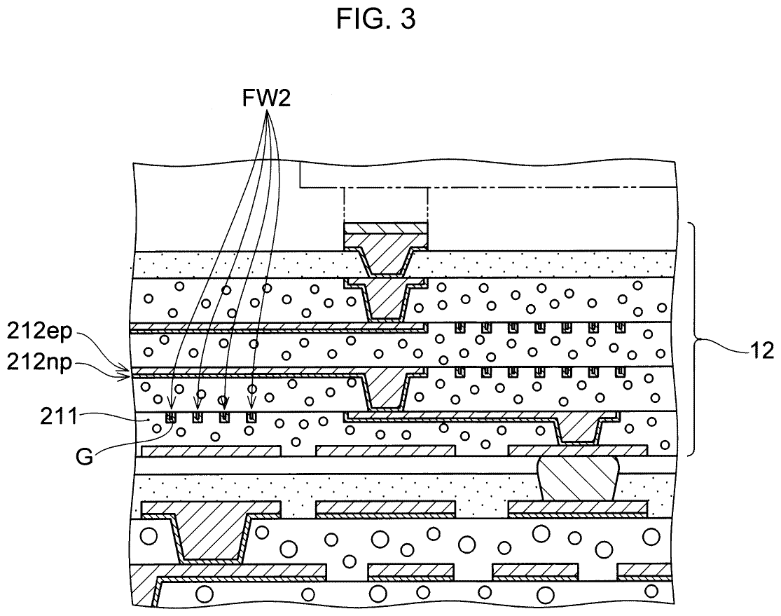

FIG. 3 illustrates a cross-sectional view of a region corresponding to FIG. 2 in another example in which the structure of each of the second conductor layers 212 differs from the example illustrated in FIG. 2. In the example illustrated in FIG. 2, the second conductor layers 212 protrude upward from the upper surfaces of the insulating layers 211, whereas the second conductor layers 212 illustrated in FIG. 3 are embedded in the insulating layers 211 from the upper surfaces of the insulating layers 211. Specifically, in FIG. 3, the second conductor layers 212 are formed of conductors (the metal film layer (212np) and the electrolytic plating film layer (212ep)) filling grooves (G) formed in the lower-side insulating layers 211. The second wirings (FW2) included in the conductor layers 212 are formed as wirings (embedded wiring) embedded in the insulating layers 211.

The formation of the conductor layers 212 embedded downward from the upper surfaces of the insulating layers 211 as illustrated in FIG. 3 can include forming the grooves (G) in the insulating layers 211 by laser irradiation, and filling the grooves (G) with conductors (the metal film layer (212np), which can be a sputtering film layer, and the electrolytic plating film layer (212ep)). Further, the process of filling the grooves (G) with the conductors can include a process of removing, by polishing, the metal film layer (212np) and the electrolytic plating film layer (212ep) formed over a depth greater than that of the grooves (G). Therefore, similar to the conductor layers 212 described with reference to FIG. 2, for the second conductor layers 212 embedded in the insulating layers 211 illustrated in FIG. 3, the upper surfaces of the conductor layers 212 can also be polished surfaces.

In particular, as illustrated, when the second wirings (FW2) are embedded wirings, since the inorganic filler particles contained in the insulating layers 211 have relatively small particle sizes (specifically, since the maximum particle size of the filler particles is relatively small), it may be possible that transmission quality of signals carried by the second wirings (FW2) is improved. Specifically, in the formation of the wirings (FW2), when the grooves (G) are formed, the inorganic filler particles may be exposed in the grooves (G). In this case, since the particle sizes of the inorganic filler particles are relatively small, it may be possible that a change in cross-sectional area along a length direction of each of the wirings (FW2) to be formed is suppressed. Insertion loss of signals carried by the second wirings (FW2) can be reduced.

As an example of the wiring substrate of the embodiment, the wiring substrate 1 including the first wiring substrate 11 and the second wiring substrate 12 has been described above. However, the second wiring substrate included in the wiring substrate of the embodiment may further include components mounted on the second wiring substrate. When the components (E1, E2) are included in the wiring substrate, the connecting pads (E1p, E2p) of the components (E1, E2) are connected to the connecting elements (12MP), and the components (E1, E2) are sealed with a sealing resin (M) containing an epoxy resin or the like, and can be integrally bonded to the second wiring substrate 12 (see FIG. 1). That is, the wiring substrate of the embodiment may include a second wiring substrate having a form of a multi-chip package device. In this case, a thermal expansion coefficient of the sealing resin (M) may be larger than a thermal expansion coefficient of the first wiring substrate and smaller than a thermal expansion coefficient of the second wiring substrate. Thermal deformation of the wiring substrate 1 in response to temperature changes may be mitigated and suppressed to a relatively small deformation.

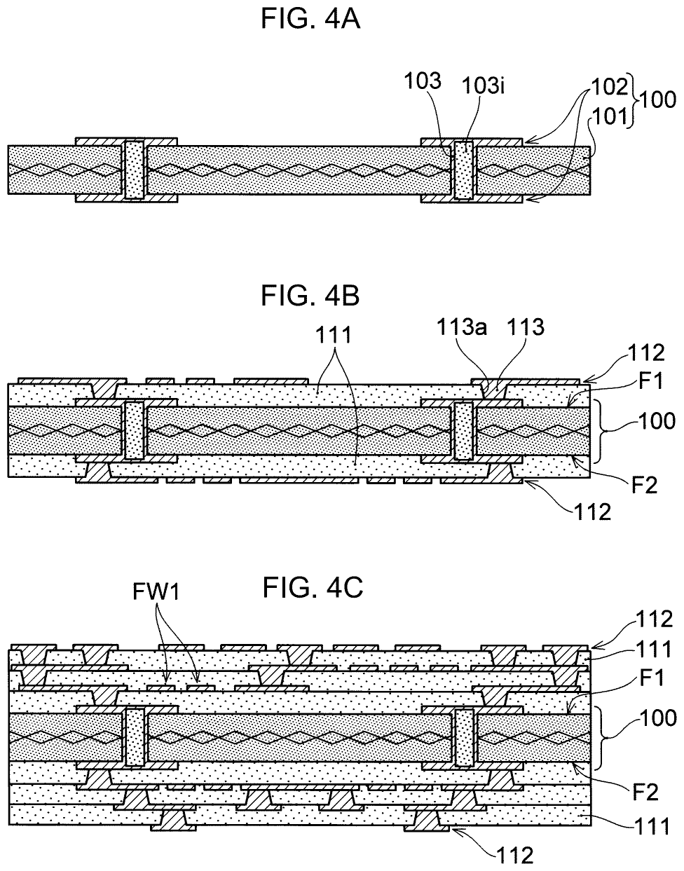

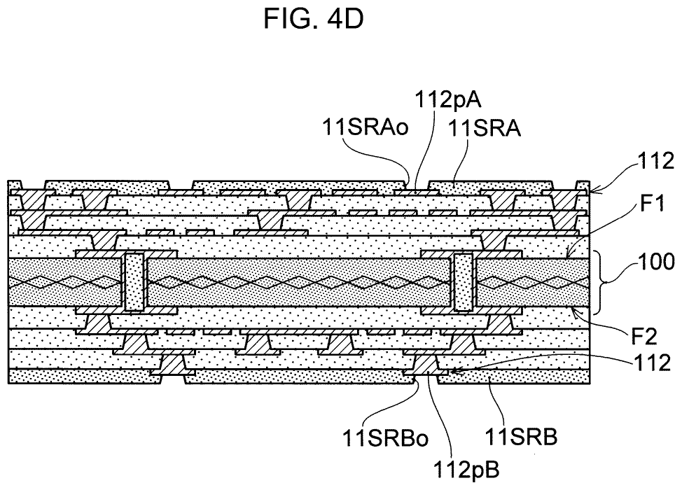

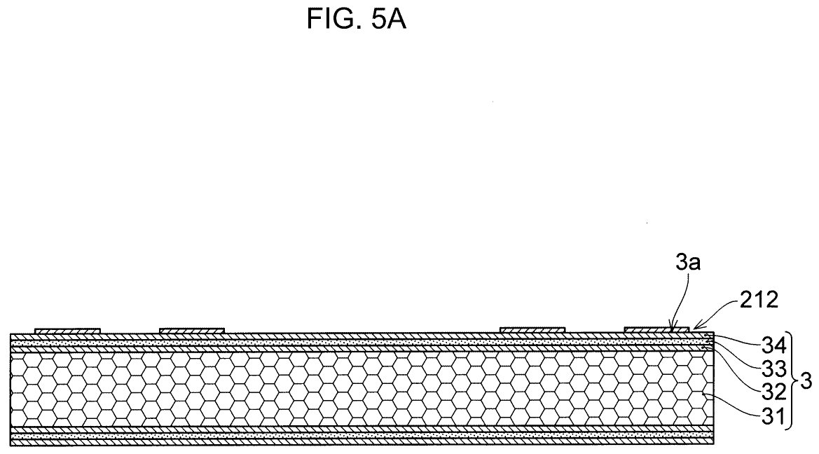

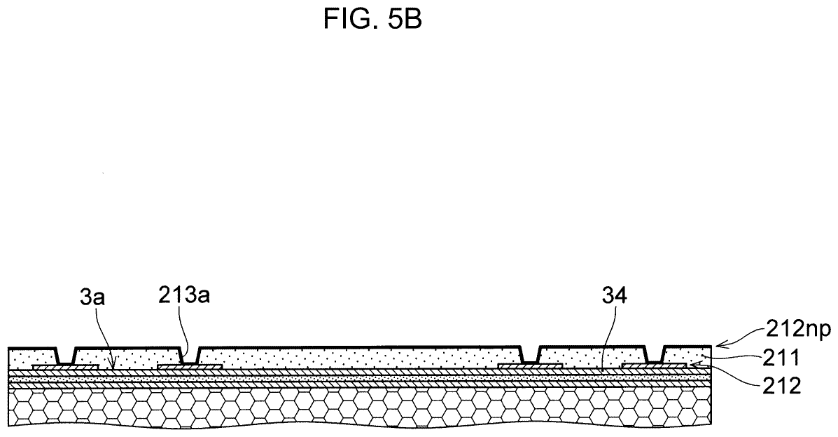

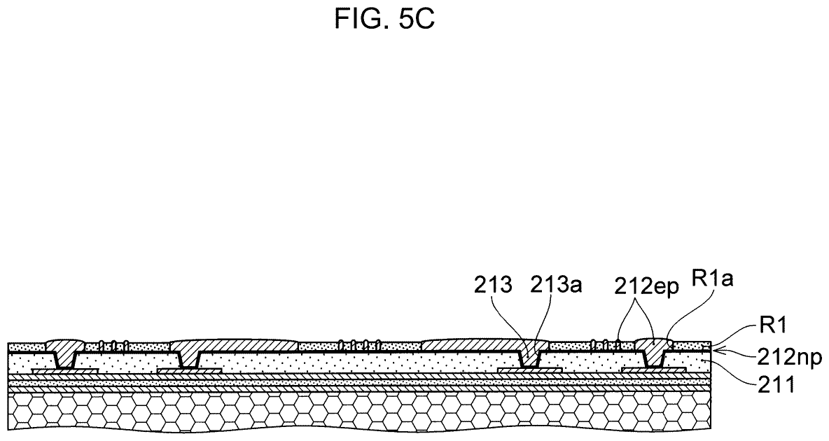

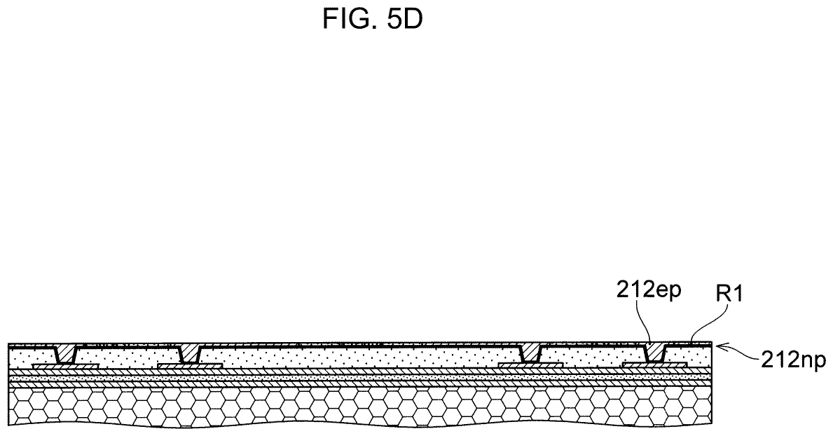

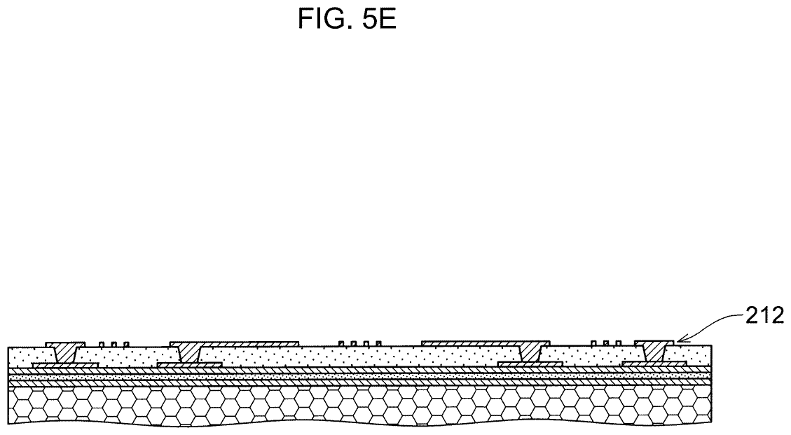

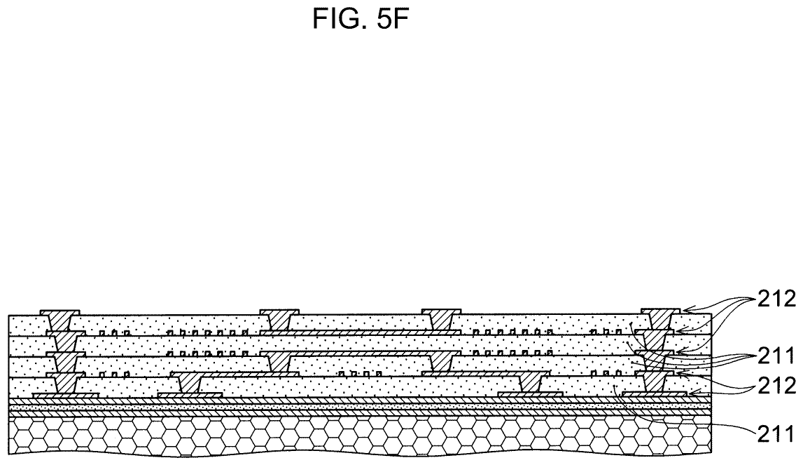

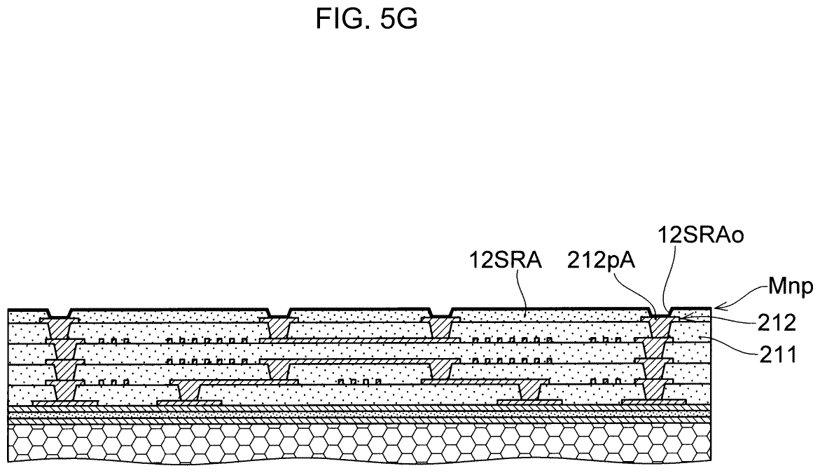

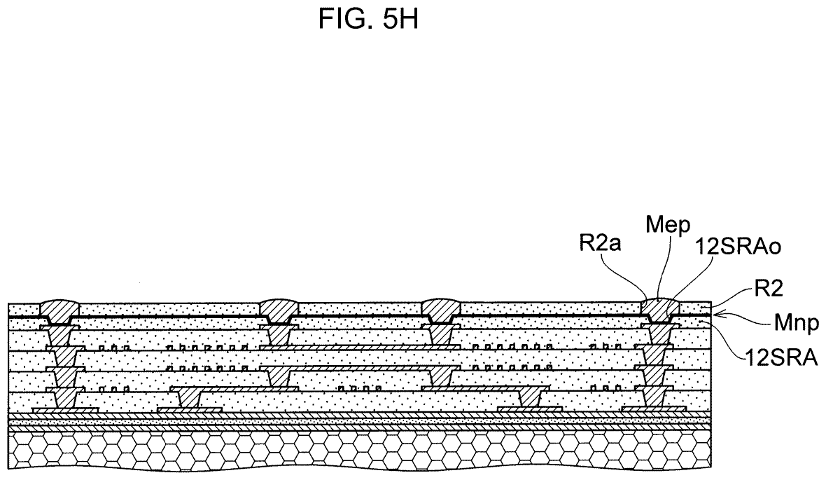

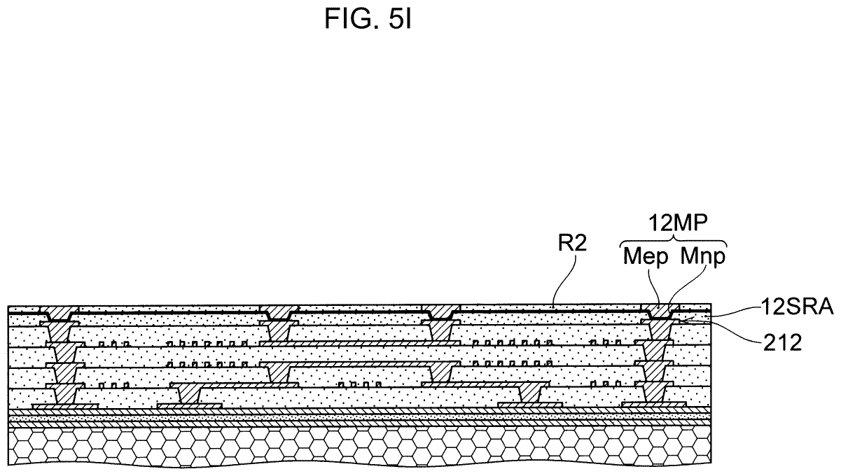

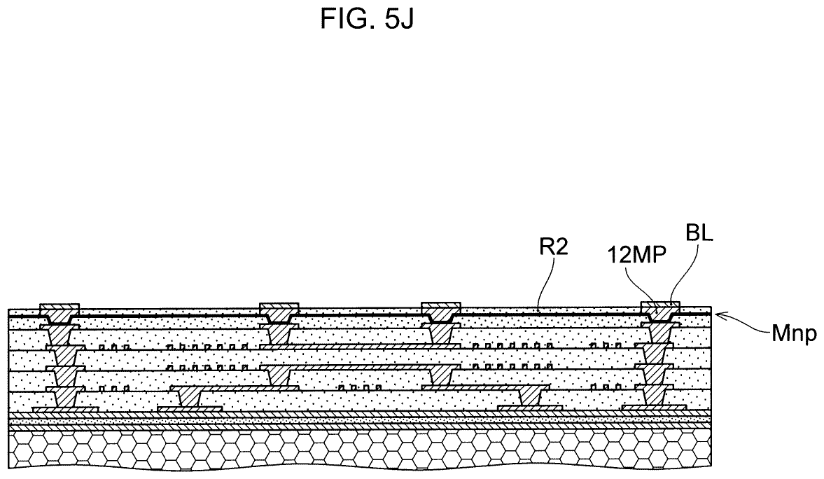

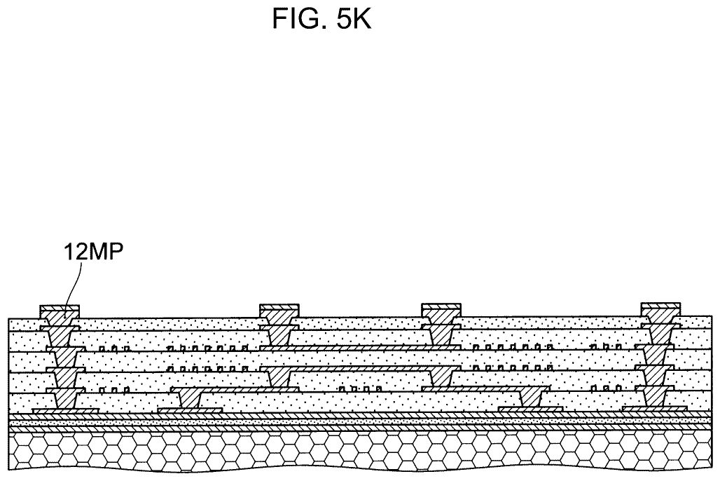

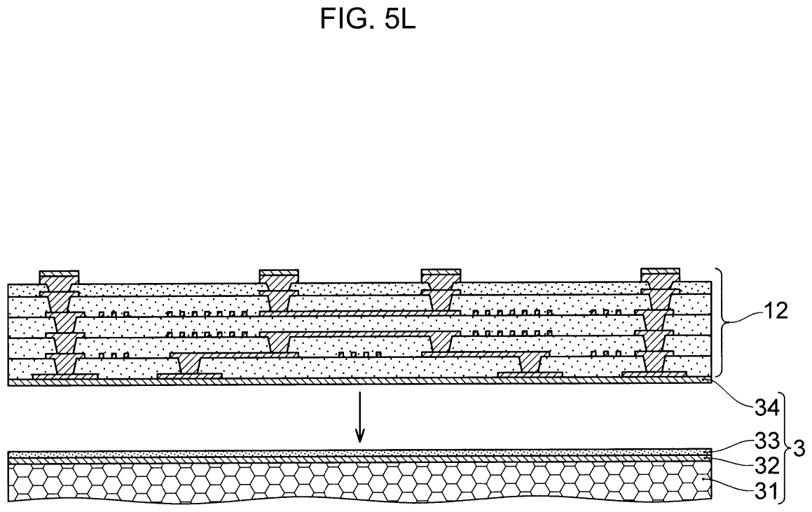

Next, with reference to FIGS. 4A-5L, a method for manufacturing a wiring substrate is described using a case where the wiring substrate 1 illustrated in FIG. 1 is manufactured as an example.

With reference to FIGS. 4A-4D, a method for manufacturing the first wiring substrate 11 is described. In manufacturing the first wiring substrate 11, first, as illustrated in FIG. 4A, the core substrate 100 is prepared. For example, a double-sided copper-clad laminated plate including the core insulating layer 101 is prepared. Through holes are formed in the double-sided copper-clad laminated plate, for example, by drilling. For example, an electroless plating film layer is formed on inner walls of the through holes and on the upper surface of the metal foil, and an electrolytic plating film layer is formed on the electroless plating film layer using the electroless plating film layer as a power feeding layer. As a result, although illustrated as having a single-layer structure in the drawing, the through-hole conductors 103 are formed that have a two-layer structure including the electroless plating film layer and the electrolytic plating film layer and cover the inner walls of the through holes. Inner sides of the through-hole conductors 103 are each filled with a resin body (103i), for example, by injecting an epoxy resin. After the filling resin bodies (103i) are solidified, on the resin bodies (103i) and the upper surface of the electrolytic plating film layer, an electroless plating film layer and an electrolytic plating film layer are further formed. As a result, although illustrated as each having a single-layer structure, the conductor layers 102 each having a five-layer structure including the metal foil layer, the electroless plating film layer, the electrolytic plating film layer, the electroless plating film layer, and the electrolytic plating film layer are respectively formed on both sides of the insulating layer 101. Then, the core substrate 100 having predetermined conductor patterns is obtained by patterning the conductor layers 102 using a subtractive method.

Next, as illustrated in FIG. 4B, an insulating layer 111 is formed on each of the first surface (F1) and the second surface (F2) of the core substrate 100, and a conductor layer 112 is formed on the upper side (the side farther from the core substrate 100) of the insulating layer 111. For example, the insulating layer 111 is formed by thermocompression bonding a film-like insulating resin onto the core substrate 100. The insulating layer 111 may be formed of a material containing inorganic filler particles. The conductor layer 112 is formed using any method for forming conductor patterns, such as a semi-additive method, at the same time as first via conductor 113 filling openings (113a) that can be formed in the insulating layer 111, for example, using laser.

Next, as illustrated in FIG. 4C, the lamination of an insulating layer 111 and a conductor layer 112 on the first surface (F1) side and on the second surface (F2) side of the core substrate 100 is repeated as many times as necessary. The conductor layers 112 are formed to include the wirings (FW1) as conductor patterns.

Next, as illustrated in FIG. 4D, the insulating layer (11SRA) is formed on the conductor layer 112 furthest from the core substrate 100 on the first surface (F1) side of the core substrate 100, and the insulating layer (11SRB) is formed on the conductor layer 112 furthest from the core substrate 100 on the second surface (F2) side. The openings (11SRAo, 11SRBo) exposing the conductor pads (112pA, 112pB) are formed in the covering insulating layers (11SRA, 11SRB). For example, the covering insulating layers (11SRA, 11SRB) can each be formed by forming a photosensitive epoxy resin film by spray coating, curtain coating, or film pasting, or the like, and the openings (11SRAo, 11SRBo) can be formed by exposure and development. The manufacture of the first wiring substrate 11 is completed.

Next, with reference to FIGS. 5A-5L, a method for manufacturing the second wiring substrate 12 is described. First, as illustrated in FIG. 5A, a support 3 is prepared, and a conductor layer 212 is formed on a surface (3a) of the support 3. The support 3 includes a base material 31, a first metal film layer 32, a release layer 33, and a second metal film layer 34.

The conductor layer 212 is formed, for example, by pattern plating using electrolytic plating. On the second metal film layer 34, which forms the surface (3a) of the support 3, a plating resist (not illustrated) is provided having openings corresponding to formation positions of the conductor patterns such as the conductor pads (212pB) to be included in the conductor layer 212. Then, by electrolytic plating using the second metal film layer 34 as a power feeding layer, a metal such as copper is deposited in the openings of the plating resist, and the conductor layer 212 is formed including conductor patterns formed of the deposited metal. After that, the plating resist is removed. Before the removal of the plating resist, the upper surface of the conductor layer 212 (the surface on an opposite side with respect to the support 3) may be polished, for example, using any method such as chemical mechanical polishing (CMP). For example, the conductor layer 212 can be formed to have a thickness of 7 μm or less.

As illustrated in FIG. 5B, an insulating layer 211 covering the conductor layer 212 is formed on the second metal film layer 34. The insulating layer 211 is formed, for example, by laminating and thermocompression bonding a film-like epoxy resin on the second metal film layer 34 and the conductor layer 212. Other than an epoxy resin, the insulating layer 211 can also be formed using a thermosetting resin such as a BT resin or a phenol resin, or a thermoplastic resin such as a fluorine resin or LCP. For example, the insulating layer 211 can be formed using a material having a relative permittivity of 0.005 or less and a dielectric loss tangent of 4.0 or less at a frequency of 5.8 GHz. Further, the insulating layer 211 can be formed of a material containing inorganic filler particles having a maximum particle size smaller than the maximum particle size of the inorganic filler particles that can be contained in the insulating layers 111 of the first wiring substrate 11. For example, in the formation of the insulating layer 211, a material containing inorganic filler particles having a maximum particle size of 1 μm or less can be used. In FIG. 5B, and in FIGS. 5C-5L to be referenced below, depiction of the opposite side with respect to the surface (3a) side of the support 3 is omitted.

Openings (213a) are formed in the insulating layer 211 at formation positions of the via conductors 213 (see FIG. 1) by irradiating CO₂ laser or the like. According to dimensions of the via conductors 213 to be formed, the openings (213a) can be formed, for example, such that a ratio of a depth from an upper surface of the insulating layer 211 to a bottom part of an opening (213a) to a diameter of the opening (213a) at an upper side (opposite side with respect to the conductor layer 212) is 0.5 or more and 1.0 or less. After the formation of the openings (213a), preferably, a desmear treatment is performed in which resin residues (smears) remaining in the openings (213a) are removed. The desmear treatment may be a wet treatment including immersion in a chemical such as a permanganate solution. However, for example, the desmear treatment may also be a dry treatment such as a plasma treatment using a plasma gas such as argon, methane tetrafluoride, a mixture of methane tetrafluoride and oxygen, or sulfur hexafluoride.

Then, in the openings (213a) and on the entire surface of the insulating layer 211, a metal film layer (212np) formed of, for example, copper or nickel or the like is formed by, for example, sputtering or electroless plating. When the metal film layer (212np) is formed by sputtering, it may be possible that a metal film layer (21np) exhibiting high adhesion with the insulating layer 211 is formed.

Next, as illustrated in FIG. 5C, a plating resist (R1) having openings (R1a) is provided on the metal film layer (212np). The plating resist (R1) is formed, for example, by laminating a dry film resist onto the metal film layer (212np), and the openings (R1a) are formed, for example, using a photolithography technology. The openings (R1a) are formed in patterns corresponding to the conductor patterns to be included in the conductor layer 212 (see FIG. 1) formed on the insulating layer 211.

The conductor patterns such as the wirings (FW2) (see FIG. 1) included in conductor layer 212 have a wiring width of 3 μm or less and an inter-wiring distance of 3 μm or less, as described above. The openings (R1a) are formed to have opening widths and inter-opening distances (distances between adjacent openings (R1a)) corresponding to wiring widths and inter-wiring distances of conductor patterns such as the wirings (FW2) to be formed in the openings (R1a). Further, as described above, the wirings (FW2) included in the conductor layer 212 have an aspect ratio of 2.0 or more and 4.0 or less. Therefore, in the method illustrated in FIG. 5C, the plating resist (R1) is formed having a thickness (height) equal to or greater than the thickness (height) that satisfies the aspect ratio of the wirings (FW2) to be formed.

An electrolytic plating film layer (212ep) formed of, for example, copper or nickel or the like is formed in the openings (R1a) of the plating resist (R1) by electrolytic plating using the metal film layer (212np) as a power feeding layer. Via conductors 213 are formed in the openings (213a) of the insulating layer 211. As in the example of FIG. 5C, the electrolytic plating film layer (212ep) can be formed to entirely fill the openings (R1a) and further have a curved upper surface protruding upward from the upper surface of the plating resist (R1).

As illustrated in FIG. 5D, an upper-side portion of the electrolytic plating film layer (212ep) is removed by polishing. At least a portion of the electrolytic plating film layer (212ep) that protrudes from the upper surface of the plating resist (R1) can be removed. The electrolytic plating film layer (212ep) can be polished until a total thickness of the metal film layer (212np) and the electrolytic plating film layer (212ep) reaches a thickness required for the conductor layer 212 (see FIG. 5E) formed on the insulating layer 211, for example, 7 μm or less. An upper-side portion of the plating resist (R1) may also be removed along with the portion of the electrolytic plating film layer (212ep). The polishing of the electrolytic plating film layer (212ep) can be performed, for example, using any method such as CMP. As a result of the polishing, the upper surface of the electrolytic plating film layer (212ep) can have an arithmetic mean roughness of 0.3 μm or less.

After the polishing of the electrolytic plating film layer (212ep), the plating resist (R1) is removed. Further, a portion of the metal film layer (212np) that is not covered by the electrolytic plating film layer (212ep) is removed, for example by quick etching or the like. As a result, as illustrated in FIG. 5E, the conductor layer 212 including predetermined conductor patterns is obtained. In FIG. 5E, similar to FIG. 1, the conductor layer 212 is depicted as having only one layer. However, the conductor layer 212 is formed of the metal film layer (212np) illustrated in FIG. 5D and the electrolytic plating film layer (212ep) after a portion thereof is removed from the state of FIG. 5D as described above.

As illustrated in FIG. 5F, on the insulating layer 211 and the conductor layer 212, additional insulating layers 211 and conductor layers 212 are further alternately formed using the same method as described above for forming the insulating layer 211 and the conductor layer 212 on the insulating layer 211.

Next, as illustrated in FIGS. 5G-5I, the covering insulating layer (12SRA) and the connecting elements (12MP) (see FIG. 5I) are formed. The connecting elements (12MP) can be formed, for example, using a method for forming a conductor layer, such as a semi-additive method. However, FIGS. 5G-5I illustrate a method including polishing similar to the method for forming the conductor layer 212 described above. First, as illustrated in FIG. 5G, the covering insulating layer (12SRA) is formed on the conductor layer 212 and the insulating layer 211. Similar to the formation of the insulating layer 211, the covering insulating layer (12SRA) is formed, for example, by thermocompression bonding of a film-like epoxy resin. When the covering insulating layer (12SRA) is an insulating layer functioning as a solder resist, the covering insulating layer (12SRA) may be formed using a method different from the insulating layer 211, for example, using a method such as spraying or curtain coating using an epoxy resin or polyimide resin or the like containing a photosensitizer.

The openings (12SRAo) are formed in the covering insulating layer (12SRA), for example, by CO₂ laser irradiation or photolithography. The openings (12SRAo) are formed at positions where the connecting elements (12MP) (see FIG. 51) are to be formed, exposing the conductor pads (212pA) at bottoms of the openings (12SRAo). After forming the openings (12SRAo), a desmear treatment, such as a plasma treatment, may be performed. A metal film layer (Mnp) formed of, for example, copper or nickel or the like, is formed on inner surfaces of the openings (12SRAo) and on the entire surface of the covering insulating layer (12SRA) by sputtering or electroless plating.

Next, as illustrated in FIG. 5H, a plating resist (R2) is formed on the metal film layer (Mnp), for example, by laminating a dry film resist. Openings (R2a) corresponding to the connecting elements (12MP) are formed in the plating resist (R2) by photolithography or the like. On inner surfaces of the openings (R2a) and in the openings (12SRAo) exposed in the openings (R2a), a metal such as copper or nickel or the like is deposited by electrolytic plating using the metal film layer (Mnp) as a power feeding layer, and an electrolytic plating film layer (Mep) is formed. The openings (R2a) and the openings (12SRAo) are filled with the electrolytic plating film layer (Mep). As illustrated, the electrolytic plating film layer (Mep) may be formed to have a curved upper surface that protrudes upward from the upper surface of the plating resist (R2).

Next, as illustrated in FIG. 5I, an upper-side portion of the electrolytic plating film layer (Mep) is removed by CMP. An upper-side portion of the plating resist (R2) may also be removed along with the portion of the electrolytic plating film layer (Mep). The electrolytic plating film layer (Mep) is polished until a height from the upper surface of the conductor layer 212 in contact with the metal film layer (Mnp) to the upper surface of the electrolytic plating film layer (Mep) reaches a predetermined height required for the connecting elements (12MP). As a result, the connecting elements (12MP) are formed that are formed of the metal film layer (Mnp) and the electrolytic plating film layer (Mep) after polishing and have the predetermined height.

Next, as illustrated in FIG. 5J, the functional layer (BL) can be formed on surfaces of the connecting elements (12MP) by, for example, electrolytic plating using the metal film layer (Mnp) as a power feeding layer. For example, a metal film of one or more layers formed of nickel, tin, palladium, gold, or the like is formed as the functional layer (BL).

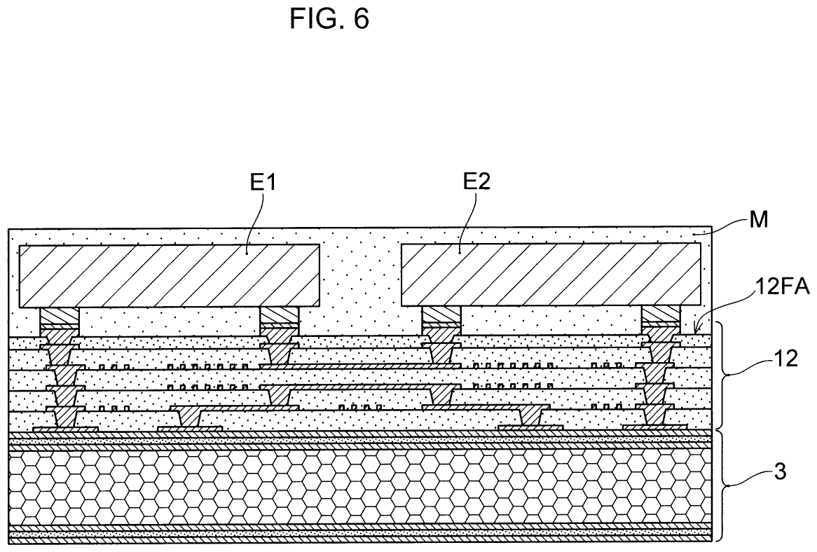

Subsequently, the plating resist (R2) is removed, and further, a portion of the metal film layer (Mnp) exposed by the removal of the plating resist (R2) that is not covered by the electrolytic plating film layer (Mep) is removed, for example, by quick etching. As illustrated in FIG. 5K, the multiple connecting elements (12MP) that are electrically separated from each other are obtained. In FIGS. 5G-5J, the metal film layer (Mnp) and the electrolytic plating film layer (Mep) that form the connecting elements (12MP) are illustrated as separate layers. However, in FIGS. 5K, 5L and 6, similar to FIG. 1, the metal film layer (Mnp) and the electrolytic plating film layer (Mep) that form the connecting elements (12MP) are collectively illustrated as a single layer.

Next, the support 3 is removed. As illustrated in FIG. 5L, for example, in a state in which the release layer 33 provided in the support 3 loses its adhesiveness or the release layer 33 itself is softened due to heating or ultraviolet irradiation or the like, the base material 31 and the first metal film layer 32 are pulled apart from the second metal film layer 34.

Next, the second metal film layer 34 is removed by etching or the like. The surfaces of the conductor layer 212 (including the conductor pads (212pB)) and the insulating layer 211 are exposed. Through the above processes, the second wiring substrate 12 in the example illustrated in FIG. 1 is completed.

Next, the second wiring substrate 12 is mounted on the first wiring substrate 11, completing the manufacture of the wiring substrate 1 illustrated in FIG. 1. Specifically, the B surface (12FB) of the second wiring substrate 12 is positioned to face the surface (11FA) of the first wiring substrate 11, and the conductor pads (212pB) of the second wiring substrate 12 and the conductor pads (112pA) of the first wiring substrate 11 are connected via the connecting members (BM). For example, the second wiring substrate 12 can be mounted on the first wiring substrate 11 through: positioning of the connecting members (BM), which are solder balls, on the conductor pads (112pA); positioning of the conductor pads (212pB) of the second wiring substrate 12 on the connecting members (BM); and a reflow process. The manufacture of the wiring substrate 1 illustrated in FIG. 1 is completed.

FIG. 6 illustrates an example of a state of the wiring substrate in a manufacturing process when the wiring substrate includes the components (E1, E2) (see FIG. 1) mounted on the surface (the A surface (12FA)) of the second wiring substrate 12. As illustrated in FIG. 6, in the manufacturing process of the second wiring substrate 12 having a form of a multi-chip package device, after the state in the process illustrated in FIG. 5K, the first component (E1) and the second component (E2), which are, for example, microcomputers or memories or the like, are mounted on the second wiring substrate 12 by reflow processing, flip chip bonding, or the like. That is, the first component (E1) and the second component (E2) are mounted on the second wiring substrate 12 with the support 3 still provided. Since the second wiring substrate 12 is supported by the support 3, the first component (E1) and the second component (E2) can be mounted in a stable state.

In the example of FIG. 6, the first component (E1) and second component (E2) can be further bonded to each other by being integrally sealed with the sealing resin (M) containing an epoxy resin or the like. The first component (E1) and the second component (E2) are sealed, for example, by transfer molding or compression molding. This sealing process can also be performed in the state in which the second wiring substrate 12 is provided with the support 3.

The second wiring substrate 12, on which the first component (E1) and the second component (E2) are mounted, as illustrated in FIG. 6, is removed from the support 3 and mounted on the first wiring substrate 11, as described with reference to FIG. 5L. The formation of the wiring substrate including the first component (E1) and the second component (E2) is completed.

The wiring substrate of the embodiment is not limited to those having the structures illustrated in the drawings and those having the structures, shapes, and materials exemplified herein. For example, the first wiring substrate and the second wiring substrate can each have any number of insulating layers and any number of conductor layers. In the description of the embodiment, an example is described in which the first wiring substrate has a core substrate. However, it is also possible that the first wiring substrate is a coreless substrate that does not include a core substrate.

Japanese Patent Application Laid-Open Publication No. 2020-191323 describes a semiconductor package that includes a first wiring substrate and a second wiring substrate. The second wiring substrate is integrally bonded to the first wiring substrate. The second wiring substrate is an organic wiring substrate using an organic insulating film as a base material, and has finer wiring layers than the first wiring substrate. The entire contents of this publication are incorporated herein by reference.

It is thought that in the semiconductor package having the first wiring substrate and second wiring substrate described in Japanese Patent Application Laid-Open Publication No. 2020-191323, an aspect ratio of wirings included in the wiring layers may be relatively low, and reliability of the wirings may be relatively low.

A wiring substrate according to an embodiment of the present invention includes: a first wiring substrate that includes alternately laminated first insulating layers and first conductor layers, and first via conductors penetrating the first insulating layers; and a second wiring substrate that includes alternately laminated second insulating layers and second conductor layers, and second via conductors penetrating the second insulating layers. The second wiring substrate is mounted on a surface on one side of the first wiring substrate. A minimum wiring width of wirings included in the second conductor layers is smaller than a minimum wiring width of wirings included in the first conductor layers. A minimum inter-wiring distance of the wirings included in the second conductor layers is smaller than a minimum inter-wiring distance of the wirings included in the first conductor layers. Wiring widths of the wirings included in the second conductor layers are 3 μm or less. Inter-wiring distances of the wirings included in the second conductor layer are 3 μm or less. An aspect ratio of the wirings included in the second conductor layer is 2.0 or more and 4.0 or less.

According to an embodiment of the present invention, it is thought that a wiring substrate including wirings with relatively high reliability is provided.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first wiring substrate comprising a plurality of first insulating layers, a plurality of first conductor layers, and a plurality of first via conductors penetrating through the first insulating layers; and
a second wiring substrate mounted on a surface of the first wiring substrate and comprising a plurality of second insulating layers, a plurality of second conductor layers, and a plurality of second via conductors penetrating through the second insulating layers,
wherein the second wiring substrate is formed such that a minimum wiring width of wirings in the second conductor layers is smaller than a minimum wiring width of wirings in the first conductor layers, a minimum inter-wiring distance of the wirings in the second conductor layers is smaller than a minimum inter-wiring distance of the wirings in the first conductor layers, wiring widths of the wirings in the second conductor layers are 3 μm or less, inter-wiring distances of the wirings in the second conductor layer are 3 μm or less, and an aspect ratio of the wirings in the second conductor layer is in a range of 2.0 to 4.0.

2. The wiring substrate according to claim 1, wherein the first and second wiring substrates are formed such that the first insulating layers and the second insulating layers include inorganic filler particles and that a maximum particle size of the inorganic filler particles in the second insulating layers is smaller than a maximum particle size of the inorganic filler particles in the first insulating layers.

3. The wiring substrate according to claim 1, wherein the second wiring substrate is formed such that the second via conductors have an aspect ratio in a range of 0.5 to 1.0.

4. The wiring substrate according to claim 1, wherein the second wiring substrate is formed such that the second insulating layers have grooves formed therein and that the wirings in the second conductor layers comprise conductors filling the grooves formed in the second insulating layers.

5. The wiring substrate according to claim 1, wherein the second wiring substrate is formed such that each of the second conductor layers has a thickness of 7 μm or less, and the first wiring substrate is formed such that each of the first conductor layers has a thickness of 10 μm or more.

6. The wiring substrate according to claim 1, wherein the second wiring substrate is formed such that the wirings in the second conductor layers have polished upper surfaces having a surface roughness of 0.3 μm or less in arithmetic mean roughness.

7. The wiring substrate according to claim 1, wherein the second wiring substrate is formed such that the second insulating layers have a dielectric loss tangent of 0.005 or less and a relative permittivity of 4.0 or less at a frequency of 5.8 GHz.

8. The wiring substrate according to claim 1, wherein the first and second wiring substrates are formed such that the wirings in each of the first and second conductor layers include a metal film layer and an electrolytic plating film layer, the metal film layer of the wirings in each of the first conductor layers is an electroless plating film layer, and the metal film layer of the wirings in each of the second conductor layers is a sputtering film layer.

9. The wiring substrate according to claim 1, wherein a projected area of the second wiring substrate onto a surface extending perpendicular to a thickness direction of the wiring substrate is smaller than a projected area of the first wiring substrate onto a surface extending perpendicular to the thickness direction of the wiring substrate.

10. The wiring substrate according to claim 1, wherein the second wiring substrate has a surface having at least a first component mounting region and a second component mounting region on an opposite side with respect to the first wiring substrate, and the second wiring substrate includes a plurality of component mounting pads formed in the first component mounting region and a plurality of component mounting pads formed in the second component mounting region and connected to the plurality of component mounting pads in the first component mounting region via the second conductor layers.

11. The wiring substrate according to claim 10, further comprising:
a first component mounted in the first component mounting region; and
a second component mounted in the second component mounting region,
wherein the first component and the second component are integrally bonded together by a sealing resin.

12. The wiring substrate according to claim 11, wherein a thermal expansion coefficient of the sealing resin is greater than a thermal expansion coefficient of the first wiring substrate and less than a thermal expansion coefficient of the second wiring substrate.

13. The wiring substrate according to claim 2, wherein the second wiring substrate is formed such that the second via conductors have an aspect ratio in a range of 0.5 to 1.0.

14. The wiring substrate according to claim 2, wherein the second wiring substrate is formed such that the second insulating layers have grooves formed therein and that the wirings in the second conductor layers comprise conductors filling the grooves formed in the second insulating layers.

15. The wiring substrate according to claim 2, wherein the second wiring substrate is formed such that each of the second conductor layers has a thickness of 7 μm or less, and the first wiring substrate is formed such that each of the first conductor layers has a thickness of 10 μm or more.

16. The wiring substrate according to claim 2, wherein the second wiring substrate is formed such that the wirings in the second conductor layers have polished upper surfaces having a surface roughness of 0.3 μm or less in arithmetic mean roughness.

17. The wiring substrate according to claim 2, wherein the second wiring substrate is formed such that the second insulating layers have a dielectric loss tangent of 0.005 or less and a relative permittivity of 4.0 or less at a frequency of 5.8 GHz.

18. The wiring substrate according to claim 2, wherein the first and second wiring substrates are formed such that the wirings in each of the first and second conductor layers include a metal film layer and an electrolytic plating film layer, the metal film layer of the wirings in each of the first conductor layers is an electroless plating film layer, and the metal film layer of the wirings in each of the second conductor layers is a sputtering film layer.

19. The wiring substrate according to claim 2, wherein a projected area of the second wiring substrate onto a surface extending perpendicular to a thickness direction of the wiring substrate is smaller than a projected area of the first wiring substrate onto a surface extending perpendicular to the thickness direction of the wiring substrate.

20. The wiring substrate according to claim 2, wherein the second wiring substrate has a surface having at least a first component mounting region and a second component mounting region on an opposite side with respect to the first wiring substrate, and the second wiring substrate includes a plurality of component mounting pads formed in the first component mounting region and a plurality of component mounting pads formed in the second component mounting region and connected to the plurality of component mounting pads in the first component mounting region via the second conductor layers.
